(19) United States
(12) Patent Application Publication
(10) Pub. No.: US 2012/0228445 A1
(43) Pub. Date: Sep. 13, 2012

(54) MOUNTING STRUCTURE

(76) Inventors: Hideyuki Hirota, Tokyo (JP); Jiro Yoshizawa, Tokyo (JP); Masahiro Kanamaru, Tokyo (JP)

(21) Appl. No.: 13/512,534

(22) PCT Filed: Mar. 25, 2010
(86) PCT No.: PCT/JP2010/002115

§ 371 Date: May 29, 2012

(51) Int. Cl. H05K 7/00; A47B 96/06

(52) U.S. Cl. 248/205.1

(57) ABSTRACT

In a mounting structure for mounting an external wall 21 of a chassis 20 made of metal on an internal wall 11 of a panel 10 made of resin, abutting portions 13 to 16 are arranged in positions separate from corners 12 of the internal wall 11 of the panel 10 to provide partial contact between the chassis and the panel.

### TECHNICAL FIELD

The present invention relates to a mounting structure of two members with different thermal expansion coefficients.

### BACKGROUND ART

When the external wall of a chassis made of metal is mounted on the internal wall of a panel made of resin, the internal wall of the panel is conventionally brought into intimate contact with the external wall of the chassis (for example, see Patent Document 1).

### PRIOR ART DOCUMENTS

### Patent Documents

Patent Document 1: JP-A-2000-102093

### SUMMARY OF THE INVENTION

However, because of a difference in thermal expansion coefficient between the metal and the resin, upon thermal contraction, the panel having a larger shrinkage cannot contract since the chassis having a smaller shrinkage is brought in intimate contact with the internal wall thereof, so that a crack occurs in a portion thereof on which stress is concentrated to be damaged, which poses a problem.

The present invention is made to solve the above-mentioned problem, and an object of the invention is to prevent the breakage of a panel upon thermal contraction.

Amounting structure according to the invention is amounting structure for mounting an external wall of a chassis made of metal on an internal wall of a panel made of resin, and an abutting portion for providing partial contact between the panel and the chassis is provided in a position separate from corners of the panel and the chassis.

According to the invention, owing to an arrangement of the abutting portion for providing partial contact between the panel and the chassis, stress concentration on the corner of the panel is released, which enables to prevent the damage thereof upon thermal contraction.

### BRIEF DESCRIPTION OF THE DRAWINGS

FIG. 1 is a sectional view showing an arrangement of amounting structure of a panel and a chassis in accordance with a first embodiment in the present invention; FIG. 1 (a) shows the structure in a normal state, and FIG. 1 (b) shows the structure in a thermally contracted state.

FIG. 2 is an exploded perspective view showing an arrangement of an electronic apparatus to which a mounting structure in accordance with the first embodiment in the invention is applied.

FIG. 3 is a perspective view showing an arrangement of the internal wall of a panel shown in FIG. 2.

FIG. 4 is a perspective view showing an arrangement where a chassis is attached to the panel shown in FIG. 3.

FIG. 5 is a sectional view of the panel and the chassis shown in FIG. 4 taken along a line A-A.

FIG. 6 is a sectional view of the panel and the chassis shown in FIG. 4 taken along a line B-B.

FIG. 7 is a sectional view showing a modification of the mounting structure in accordance with the first embodiment in the invention, and shows a thermally contracted state thereof.

### BEST MODE FOR CARRYING OUT THE INVENTION

Embodiments of the present invention will now be described with reference to the accompanying drawings in order to explain the present invention in more detail.

### First Embodiment

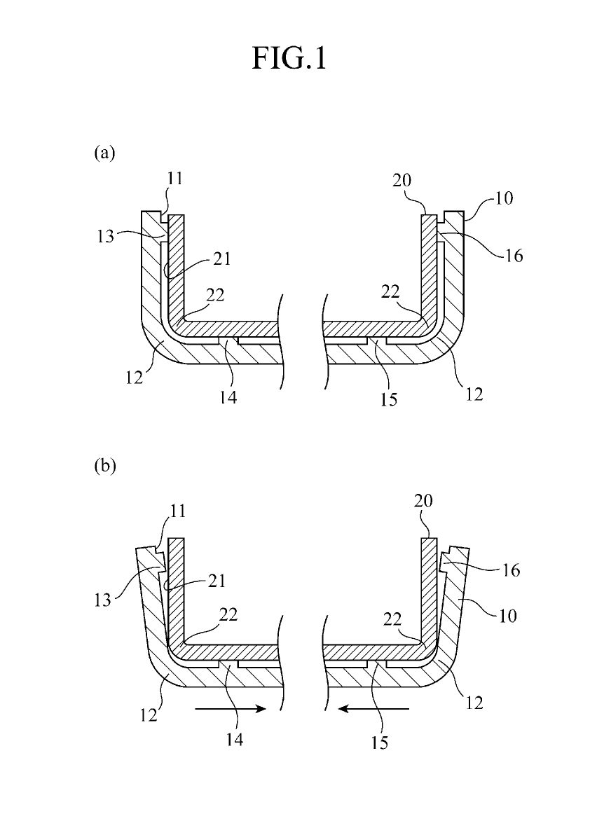

A mounting structure shown in FIG. 1(a) and FIG. 1(b) is a structure for mounting a chassis 20 made of a metal material on a panel 10 made of a resin material. The panel 10 is composed of a bottom and at least two sides opposed to each other, and has a corner 12 in a transition area between the bottom and the side. Similarly, the chassis 20 is also composed of a bottom and at least two sides opposed to each other, and has a corner 22 in a transition area between the bottom and the side. Further, the panel 10 has a larger thermal contraction due to the resin material, and is thermally contracted in the directions of arrows shown in FIG. 1(b).

Abutting portions 13 to 16 in the shape of a projection are formed on the internal wall of the panel 10 such that an internal wall 11 of the panel 10 comes in partial contact with an external wall 21 of the chassis 20 to reduce a contact area. Further, in order to avoid stress from being concentrated on the corner 12 upon thermal contraction, the abutting portions 13, 14, and the abutting portions 15, 16 are placed separate from the corners 12. Since these abutting portions 13 to 16 create clearances between the corners 12 of the panel 10 and the corners 22 of the chassis 20, the panel 10 is not hindered from being deformed as shown in FIG. 1(b) when the panel thermally contracts; thus, stress concentration on the corner 12 can be prevented. As a result, the occurrence of a crack on the corner 12 can be prevented upon the thermal contraction of the panel 10.

Furthermore, since the abutting portions 13 to 16 provide clearances between the internal wall on the corner 12 of the panel 10 and the external wall on the corner 22 of the chassis 20, the corner 12 can have an increased curvature radius R. Therefore, further stress relaxation thereof can be expected.

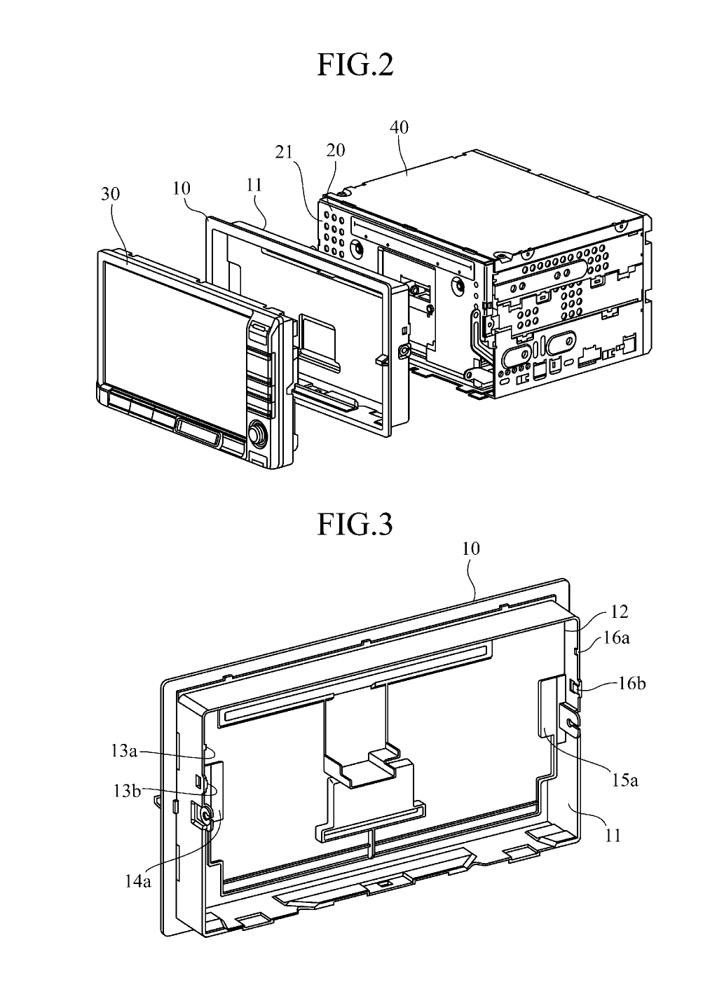

Next, an application example of the mounting structure will be discussed. Note that in FIGS. 2 to 6 shown below, the portions corresponding to those of the panel 10 and the chassis 20 discussed in FIG. 1 as mentioned above are denoted by the same or corresponding numerals. An electronic apparatus shown in FIG. 2 is arranged such that the back of the display section 30 is covered with the panel 10, and that the panel 10 is mounted on the chassis 20 covering the front of a main body section 40. As shown in FIG. 3, on the internal wall 11 of the panel 10, abutting portions 13a, 13b, and an abutting portion 14a are formed in positions separate from corners 12 on one of two sides opposed to each other, and also an abutting portion 15a and abutting portions 16a, 16b are formed in positions separate from corners 12 on the other thereof.

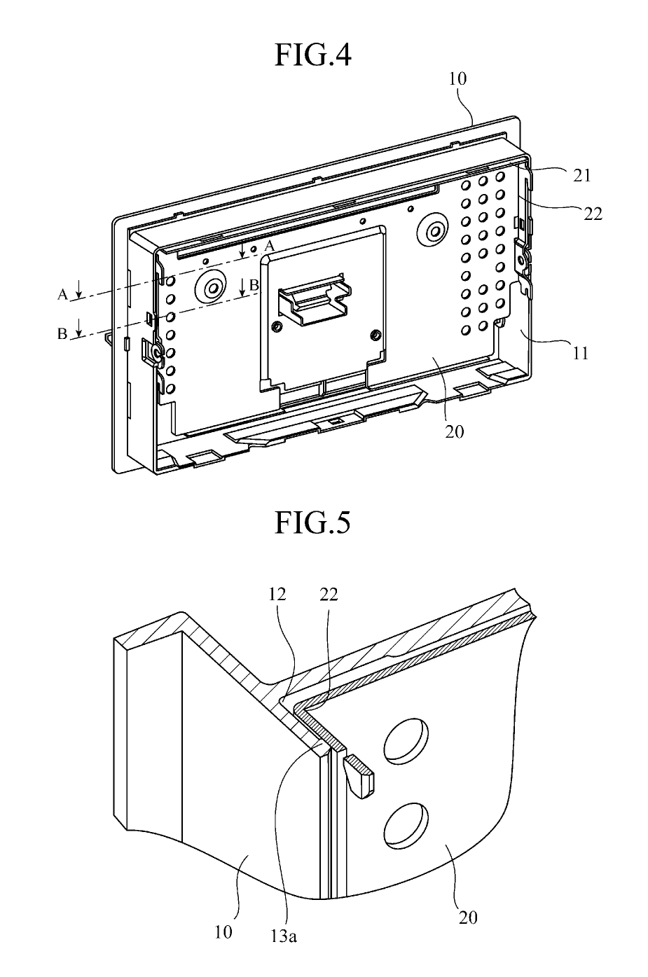

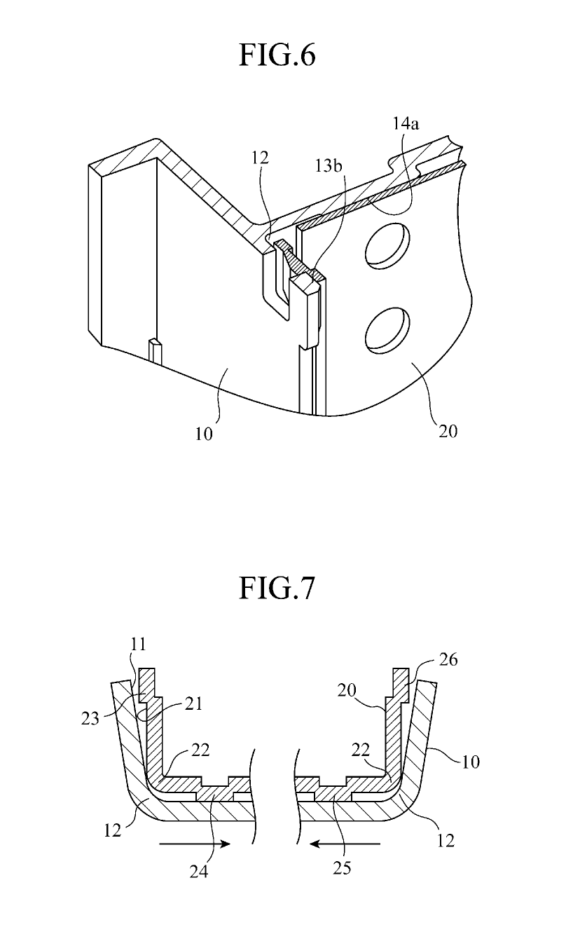

FIG. 4 shows a state where the external wall 21 of the chassis 20 is mounted on the internal wall 11 of the panel 10. FIG. 5 shows a sectional view thereof taken along a line A-A of FIG. 4, and FIG. 6 shows a sectional view thereof taken along a line B-B. As shown in FIG. 5 and FIG. 6, the abutting portions 13a, 13b, and 15a of the panel 10 each come into partial contact with the external wall 21 of the chassis 20, to thus provide clearances between the internal wall on the corner 12 of the panel 10 and the external wall on the corner 22 of the chassis 20. Therefore, when thermally contracted, the panel 10 made of resin comes to be deformable without being hindered by the corner 22, so that there is no stress concentration on the corner 12 to cause no crack therein.

The abutting portions 16a, 16b, and 15a have arrangements similar to those of the abutting portions 13a, 13b, and 15a, respectively, and thus illustrations thereof will be omitted.

As discussed above, in accordance with the first embodiment, the mounting structure for mounting the external wall 21 of the chassis 20 made of metal on the internal wall 11 of the panel 10 made of resin is arranged such that the abutting portions 13 to 16 for providing partial contact between the panel 10 and the chassis 20 are provided in positions separate from the corners 12 of the panel 10 and the corners 22 of the chassis 20. For this reason, the stress concentration on the corners 12 of the panel 10 is released, which enables to prevent the damage thereof upon thermal contraction.

Further, since the arrangement of the abutting portions 13 to 16 can form clearances between the corner 12 of the panel 10 and the corner 22 of the chassis 20, the corner 12 of the panel 10 can have a curvature radius larger than that of the corner 22 of the chassis 20. In such a way, further stress relaxation thereof can be achieved.

Hereupon, in the first embodiment, the abutting portions 13 to 16 are formed on the panel 10; however, abutting portions may be formed on the chassis 20 reversely. As illustrated in FIG. 7, even when abutting portions 24 to 26 are formed on the chassis 20 made of a metal material by drawing, hammering, or the like, the panel 10 is deformable upon thermal contraction, which enables to relieve the stress concentration on the corners.

Moreover, the abutting portion may have any shape; for example, it may be formed in a hemispheric projection to render a point contact therebetween.

### INDUSTRIAL APPLICABILITY

As discussed above, since the mounting structure according to the present invention is arranged such that partial contact is provided between the internal wall of the panel made of resin and the external wall of the chassis made of metal by using the abutting portion, it is suitable for use in a vehicle-mounted apparatus and so on used in a temperature environment where there is a possibility that resin thermally contracts.

1. A mounting structure for mounting an external wall of a chassis made of metal on an internal wall of a panel made of resin, wherein an abutting portion for providing partial contact between the panel and the chassis is provided in a position separate from corners of the panel and the chassis.

2. The mounting structure according to claim 1, wherein the abutting portion is a projection provided on the side of the panel.

3. The mounting structure according to claim 1, wherein the abutting portion is a projection provided on the side of the chassis.

4. The mounting structure according to claim 1, wherein the curvature radius on the corner of the panel is larger than that on the corner of the chassis.
